(19) United States
(12) Patent Application Publication
(10) Pub. No.: US 2007/0292982 A1
(43) Pub. Date: Dec. 20, 2007

(54) Method for Manufacturing Transparent Windows in Molded Semiconductor Packages

(76) Inventors: Jeffery Gail Holloway, Plano, TX (US); Steven Alfred Kummerl, Plano, TX (US); Bernard Peter Lange, Freising (DE)

Correspondence Address: TEXAS INSTRUMENTS INCORPORATED, P O BOX 655474, M/S 3999, DALLAS, TX, 75265, US

(21) Appl. No.: 11/424,735

(22) Filed: Jun. 16, 2006

(51) Int. Cl. H01L 21/56

(52) U.S. Cl. 438/64; 438/116

(57) ABSTRACT

Methods for packaging light-sensitive semiconductor devices in packages are described in which a transparent window aligned with light-sensitive surfaces of the devices are provided. The methods of the invention include steps for affixing a transparent body to a light-sensitive surface of the semiconductor device, affixing the device to a leadframe, and placing the assembled leadframe, device, and transparent body into a mold configured for contacting the transparent body. The assembled leadframe and device are encapsulated and removed from the mold, forming a package encased in encapsulant and having a transparent window aligned with the light-sensitive surface of the device.

### TECHNICAL FIELD

The invention relates to electronic semiconductor devices and manufacturing. More particularly, the invention relates to packaged semiconductor devices having light-sensitive portions, and to methods useful for the manufacture of semiconductor packages having transparent windows.

### BACKGROUND OF THE INVENTION

For convenience, and in the event that common usage, now or in the future, may diverge from the nomenclature used herein, the following definitions are provided to assist in the understanding of the invention. For the purposes of the describing the present invention, various portions of the electromagnetic spectrum, including ultraviolet, visible, and infrared, are referred to generally as “light”. It should be understood that in keeping with the broad meaning of the term “light” used for the purposes of describing the invention, the term “transparent” used herein denotes the ability of the referenced material to transmit a selected portion of the electromagnetic spectrum, e.g. infrared, ultraviolet, or visible, and is not restricted to the ability to transmit visible light or all light, as may be implied in casual lay usage of the term. The term “light-sensitive” is used herein to denote devices or portions of devices designed for receiving or emitting light.

Some packaged microelectronic devices require that a portion of the chip surface be sensitive to light for certain functions. For example, some EEPROM devices have an erase function that works by the receipt of UV light on the chip surface. Other examples include IR communication devices, and various optical sensors. Many such devices known in the arts are assembled in molded plastic packages. Typically for microelectronic devices, the mold compound, or encapsulant, is opaque. Therefore, in the fabrication of light-sensitive devices, a portion of the mold compound must be excluded during molding, or must be removed from the light-sensitive portion of the chip. The resulting cavity is then filled with a transparent insert or compound that acts as a window to the light-sensitive surface of the chip. It is known in the art to use a structure attached to the inside surface of the mold cavity to exclude the opaque encapsulant during molding. Because the seal of the excluding structure may not be perfect in all cases, the light-sensitive portion of the chip often requires cleaning after the molding process in order to remove stray encapsulant. Since the light-sensitive surface of the chip is delicate, such cleaning can result in damage, leading to reduced manufacturing yield, decreased sensitivity to light, or reduced reliability. Practitioners of the arts give much attention to developing cleaning processes that are both robust with respect to the contaminating opaque mold compound and gentle with respect to the light-sensitive portion of the chip.

Another approach known in the arts for the manufacture of light-sensitive device packages is the use of transparent mold compound to encase the entire package. Although simple in terms of using existing manufacturing processes, this approach is not suitable for many applications because the transparent mold compounds tend to have inferior thermal and mechanical properties compared to opaque mold compounds, resulting in decreased reliability. Due to these and other technical challenges, improved methods for manufacturing molded semiconductor device packages having transparent windows for use in light-sensitive applications would be useful and advantageous in the arts.

### SUMMARY OF THE INVENTION

In carrying out the principles of the present invention, in accordance with preferred embodiments thereof, methods for packaging semiconductor devices having light-sensitive surfaces are disclosed in which a transparent window is provided for the light-sensitive region of a device using techniques offering novel improvements and one or more advantages.

According to one aspect of the invention, a method for packaging a light-sensitive semiconductor device includes steps for affixing a transparent body to a light-sensitive surface of the semiconductor device and affixing the device to a leadframe. The assembled leadframe, device, and transparent body are placed into a mold configured to contact the transparent body. The assembled leadframe and device are encapsulated within the mold, forming a package having a transparent window aligned with the light-sensitive surface of the device.

According to another aspect of the invention, a method for packaging a light-sensitive semiconductor device includes placing a rigid transparent body on a light-sensitive surface of the semiconductor device.

According to yet another aspect of the invention, a method for packaging a light-sensitive semiconductor device includes steps for dispensing a fluid transparent material on a light-sensitive surface of the semiconductor device and shaping the fluid transparent material on the light-sensitive surface of the semiconductor device using a mold. The fluid transparent material is cured on the light-sensitive surface of the semiconductor device to form a transparent body.

According to still another aspect of the invention, preferred embodiments of methods for packaging a semiconductor device having a transparent window include steps for cleaning the transparent window.

The invention has advantages including but not limited to one or more of the following: providing manufacturing methods for packaged light-sensitive devices with reduced cleaning damage at the light-sensitive surface of the chip; providing cost-effective manufacturing methods for light-sensitive devices; decreasing yield loss during packaging of light-sensitive devices. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1A shows a cut-away side view illustrating steps in the manufacture of a packaged light-sensitive device according to an example of a preferred embodiment of methods of the invention;

FIG. 1B shows a cut-away side view illustrating further steps in the manufacture of a packaged light-sensitive device according to the example of FIG. 1A;

FIG. 1C shows a cut-away side view illustrating additional steps in the manufacture of a packaged light-sensitive device according to the example of FIGS. 1A-B;

FIG. 1D shows a cut-away side view illustrating an alternative embodiment of the invention, showing that a flip-chip may be used in place of the wirebonded chip in the steps for the manufacture of a packaged light-sensitive device according to the example of FIG. 1C;

FIG. 1E shows a cut-away side view illustrating yet further steps in the manufacture of a packaged light-sensitive device according to the example of FIGS. 1A-D;

FIG. 1F shows a cut-away side view illustrating additional steps in the manufacture of a packaged light-sensitive device according to the example of FIGS. 1A-E;

FIG. 1G shows a cut-away side view illustrating final steps in the manufacture of a packaged light-sensitive device according to the example of FIGS. 1A-F;

FIG. 2A shows a cut-away side view illustrating steps in the manufacture of a packaged light-sensitive device according to an example of an alternative preferred embodiment of methods of the invention;

FIG. 2B shows a cut-away side view illustrating further steps in the manufacture of a packaged light-sensitive device according to the example of FIG. 2A;

FIG. 2C shows a cut-away side view illustrating additional steps in the manufacture of a packaged light-sensitive device according to the example of FIGS. 2A-B;

FIG. 2D shows a cut-away side view illustrating more steps in the manufacture of a packaged light-sensitive device according to the example of FIGS. 2A-C;

FIG. 2E shows a cut-away side view illustrating yet further steps in the manufacture of a packaged light-sensitive device according to the example of FIGS. 2A-D;

FIG. 2F shows a cut-away side view illustrating final steps in the manufacture of a packaged light-sensitive device according to the example of FIGS. 2A-E;

FIG. 3A shows a cut-away side view illustrating steps in the manufacture of a packaged light-sensitive device according to an example of another alternative preferred embodiment of methods of the invention;

FIG. 3B shows a cut-away side view illustrating further steps in the manufacture of a packaged light-sensitive device according to the example of FIG. 3A;

FIG. 3C shows a cut-away side view illustrating additional steps in the manufacture of a packaged light-sensitive device according to the example of FIGS. 3A-3B.

FIG. 3D shows a cut-away side view illustrating more steps in the manufacture of a packaged light-sensitive device according to the example of FIGS. 3A-C;

FIG. 3E shows a cut-away side view illustrating yet further steps in the manufacture of a packaged light-sensitive device according to the example of FIGS. 3A-D;

FIG. 3F shows a cut-away side view illustrating final steps in the manufacture of a packaged light-sensitive device according to the example of FIGS. 3A-E;

FIG. 4A shows a cut-away side view illustrating steps in the manufacture of a packaged light-sensitive device according to an example of another alternative preferred embodiment of methods of the invention;

FIG. 4B shows a cut-away side view illustrating further steps in the manufacture of a packaged light-sensitive device according to the example of FIG. 4A;

FIG. 4C shows a cut-away side view illustrating additional steps in the manufacture of a packaged light-sensitive device according to the example of FIGS. 4A-B;

FIG. 4D shows a cut-away side view illustrating more steps in the manufacture of a packaged light-sensitive device according to the example of FIGS. 4A-C;

FIG. 4E shows a cut-away side view illustrating yet further steps in the manufacture of a packaged light-sensitive device according to the example of FIGS. 4A-D;

FIG. 4F shows a cut-away side view illustrating final steps in the manufacture of a packaged light-sensitive device according to the example of FIGS. 4A-E; and

FIG. 4G shows a cut-away side view illustrating final steps in the manufacture of a packaged light-sensitive device according to the example of FIGS. 4A-F.

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DESCRIPTION OF PREFERRED EMBODIMENTS

In general, the invention provides methods for manufacturing packaged light-sensitive devices using a transparent body captured by mold compound to form a transparent window in the package. The transparent window is aligned to transmit light to or from a light-sensitive surface of the device. The manufacturing steps are sequenced and the components are arranged in such a way that contamination of the light-sensitive surface of the chip is minimized or avoided, and/or any necessary cleaning of excess mold compound is performed at the outer window surface rather than on the light-sensitive portion of the chip.

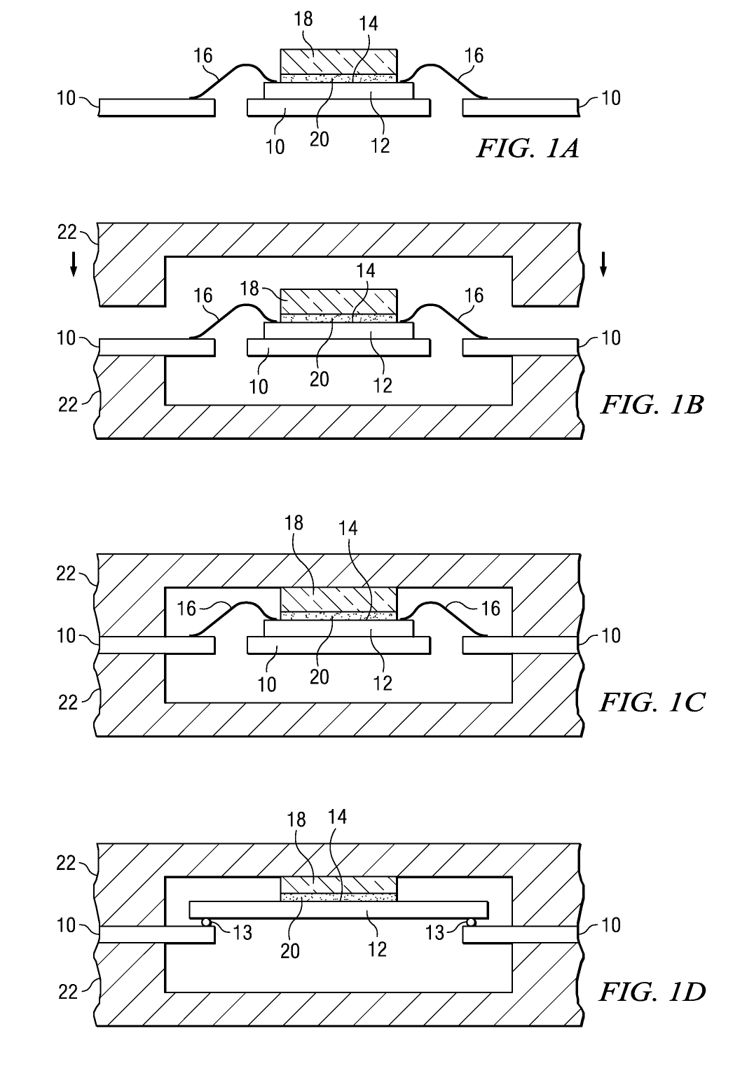

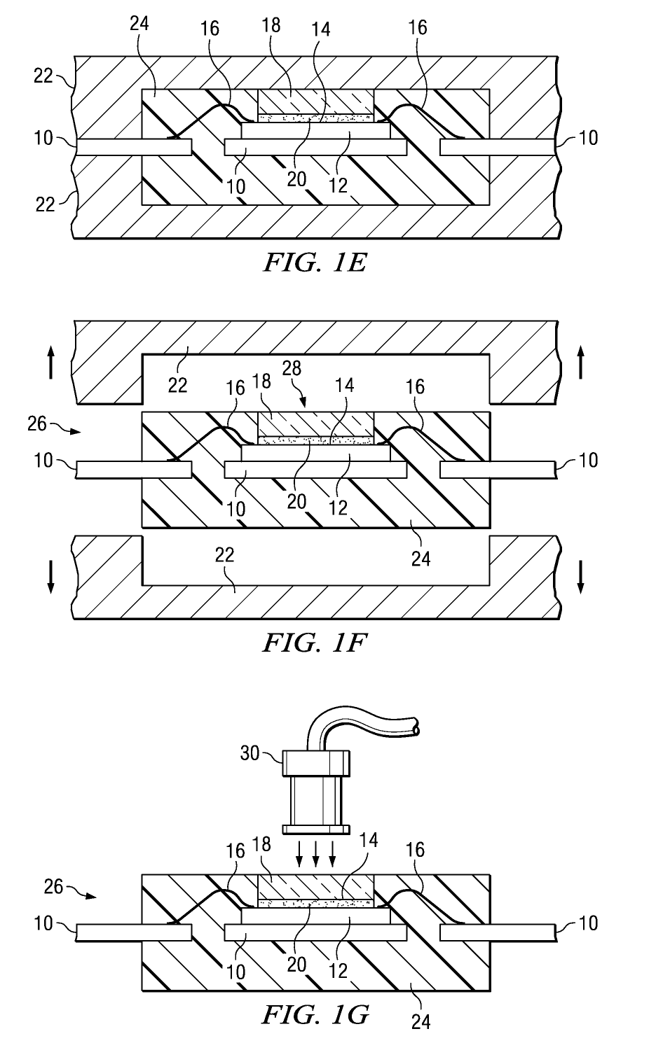

Referring first to FIGS. 1A through 1G, steps in an example of a preferred embodiment of a method according to the invention are described. As shown beginning with FIG. 1A, a leadframe 10 and chip 12 requiring light exposure to at least one portion 14 of a surface, often the backside, are preferably joined as known in the arts. Bondwires 16 are preferably used for making operable electrical connections as shown, or alternatively, surface mount connections may be used. A transparent body 18 is preferably attached to the light-sensitive portion 14 of the chip 12. The transparent body 18 may be made of various alternative materials without departure from the invention such as elastomeric material, glass, crystal, plastic, epoxy, or other material selected for transparency in the desired segment of the spectrum. A transparent adhesive 20 is used to affix the transparent body 18 to the chip 12. Preferably, the transparent adhesive 20 is an elastomeric material, gel, or other pliable, viscous, or semi-viscous material suitable for curing or hardening or otherwise forming a seal at the junction of the chip 12 and transparent body 18. Preferably, the elasticity of either the adhesive 20 or transparent body 18, or both, protects against damage to the light-sensitive portion 14 of the chip 12 when the mold 22 (FIG. 1B) makes contact with the surface of the transparent body 18 (FIG. 1C) and, as is typically the case, holds it firmly against the surface of the chip 12 to prevent the ingress of encapsulant 24 (FIG. 1E).

Now referring primarily to FIGS. 1B-1G, the leadframe 10 and chip 12, with the transparent body 18 in place, are positioned in a mold 22 (FIG. 1B). FIGS. 1C and 1D provide two alternative views of implementations of the invention using a bond wire configuration and a flip-chip configuration respectively. In FIG. 1C, bond wire connections 16 are used to couple the chip 12 to the leads of the leadframe 10. In FIG. 1D, the chip 12 shown uses surface-mount solder ball 13 connections familiar in the arts rather than the bond wire configuration of 1C and elsewhere. Such alternative configurations may be used with any of the embodiments shown and described herein without departure from the principles and practice of the invention. As shown in FIGS. 1C and 1D, the mold 22, which typically includes two pieces designed to meet, is positioned to facilitate encapsulation of at least a portion of the leadframe 10, and the chip 12. The mold 22 preferably also provides for the exclusion of mold compound 24, as shown in FIG. 1E, from at least a portion of the outer surface of the transparent body 18. The encapsulated device 26 is subsequently removed from the mold 22 as illustrated in FIG. 1F, revealing a window 28 formed by at least a part of the transparent body 18, which transmits light to the appropriate portion 14 of the chip 12. As depicted in FIG. 1G, in the event that an imperfect seal at the mold cavity or other eventualities have permitted the window 28 to become contaminated with mold compound or other material, the window 28 may be cleaned 30 using techniques known in the arts, generally employing more robust and less expensive means than might otherwise be required for cleaning the unprotected light-sensitive portion of the chip itself.

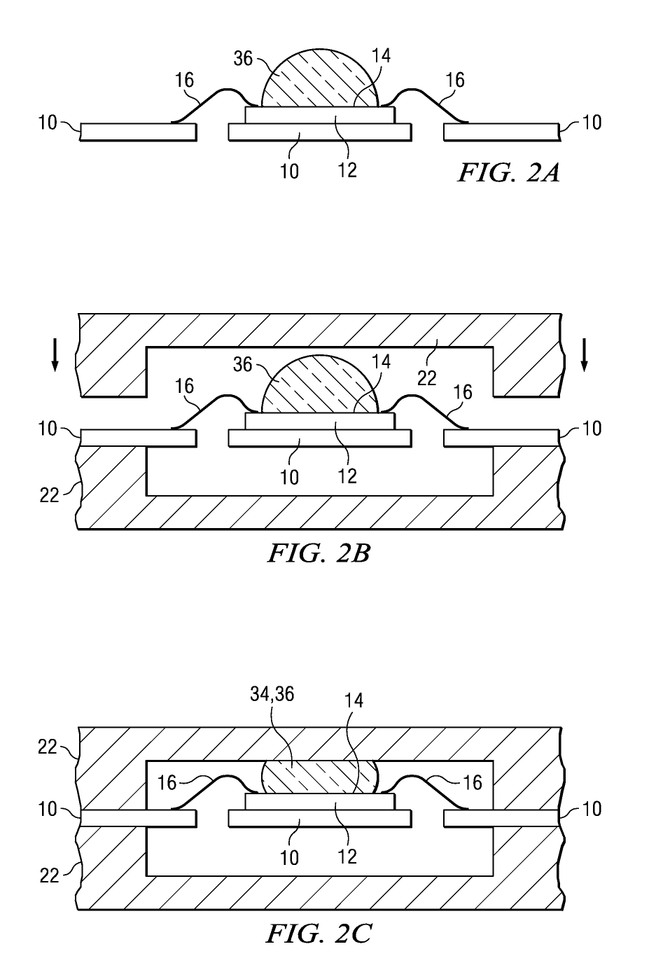

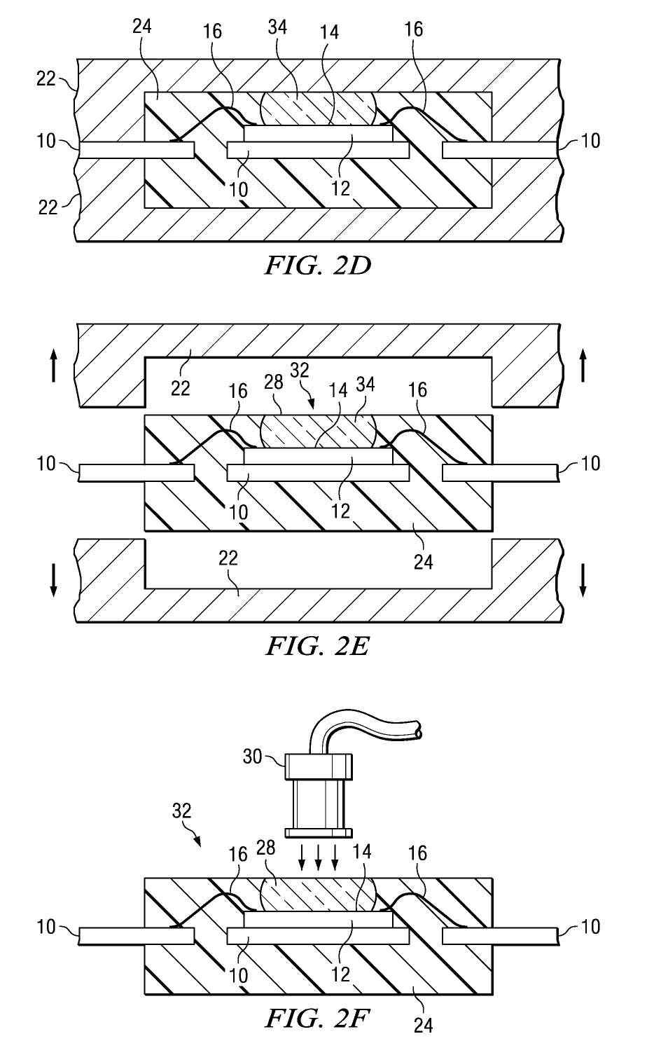

Now referring to FIGS. 2A through 2F, an alternative embodiment of a method for manufacturing a light-sensitive device package 32 is shown and described in which a transparent body 34, and thus the window 28 may be formed in a mold 22. As depicted in FIG. 2A, and as described above, a leadframe 10 and chip 12 designed for light exposure, for either receipt or transmission, to at least one light-sensitive portion 14 of a surface, are preferably joined and wirebonded 16, or flip-chipped (not shown), as known in the arts. A quantity of an uncured or partially cured fluid transparent material 36 is dispensed onto the light-sensitive portion 14 of the chip. The quantity of fluid transparent material 36 and degree of viscosity are selected based on the geometry of the particular package 32. The fluid material 36 is curable, forming a transparent rigid or elastomeric material in its cured state. As shown in FIG. 2B, the assembly thus prepared is loaded into a mold 22. Now referring primarily to FIG. 2C, the mold 22 is preferably used to complete the formation of the transparent elastomeric material 36 prior to curing to form a solid transparent body 34 (FIG. 2C). Preferably, the fluid transparent material 36 is sufficiently pliable to be shaped into the desired transparent body 34 form over the light-sensitive portion 14 of the chip 12 by the mold 22. The inflow of the opaque or non-transparent mold compound 24 used to complete the remainder of the encapsulation is preferably deferred until the fluid transparent material 36 has cured sufficiently to ensure the exclusion of encapsulant 24 from the light-sensitive portion 14 of the chip 12. After the fluid transparent material 36 cures into a sufficiently rigid transparent body 34, the mold compound 24 is preferably flowed into the mold 22 according to molding techniques familiar in the arts, as illustrated in FIG. 2D. In this alternative embodiment, the mold 22, and the transparent body 34, being tightly sealed, preferably exclude mold compound 24 from contaminating the outer surface of the transparent body 34. The package 32 is subsequently removed from the mold 22 as illustrated in FIG. 2E, revealing a window 28 formed by at least a portion of the cured transparent body 34, which transmits light to the light-sensitive portion 14 of the chip 12. As depicted in FIG. 2F, in the event that a mold defect or other eventualities have permitted the window 28 to become contaminated with mold compound or other material, the window 28 may be cleaned 30 using techniques known in the arts.

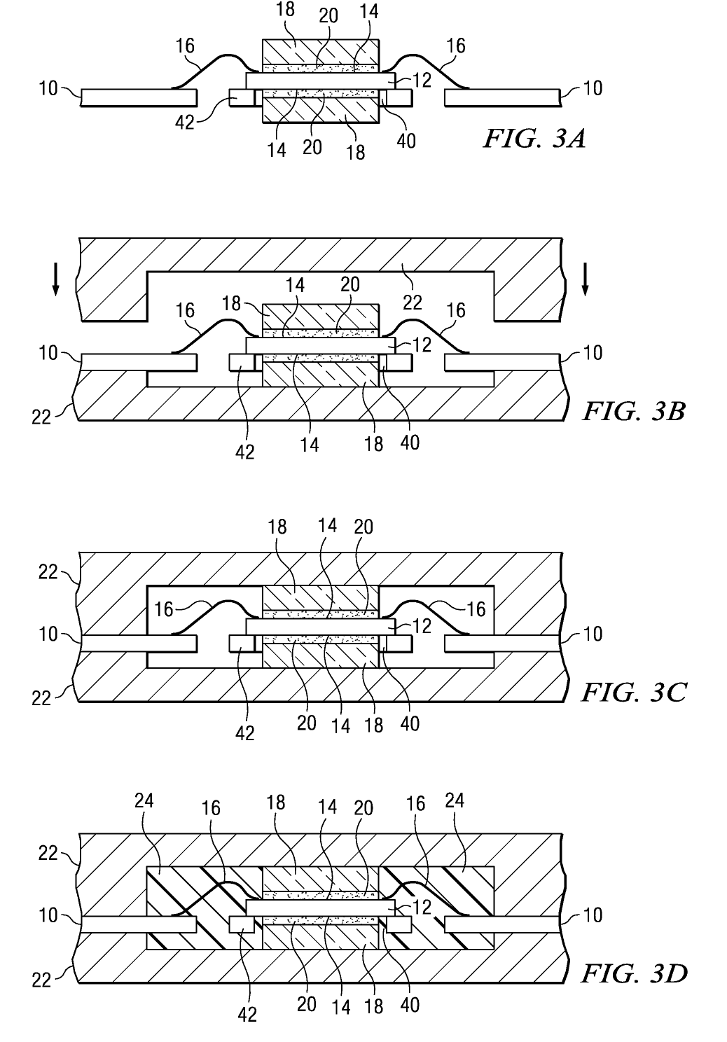

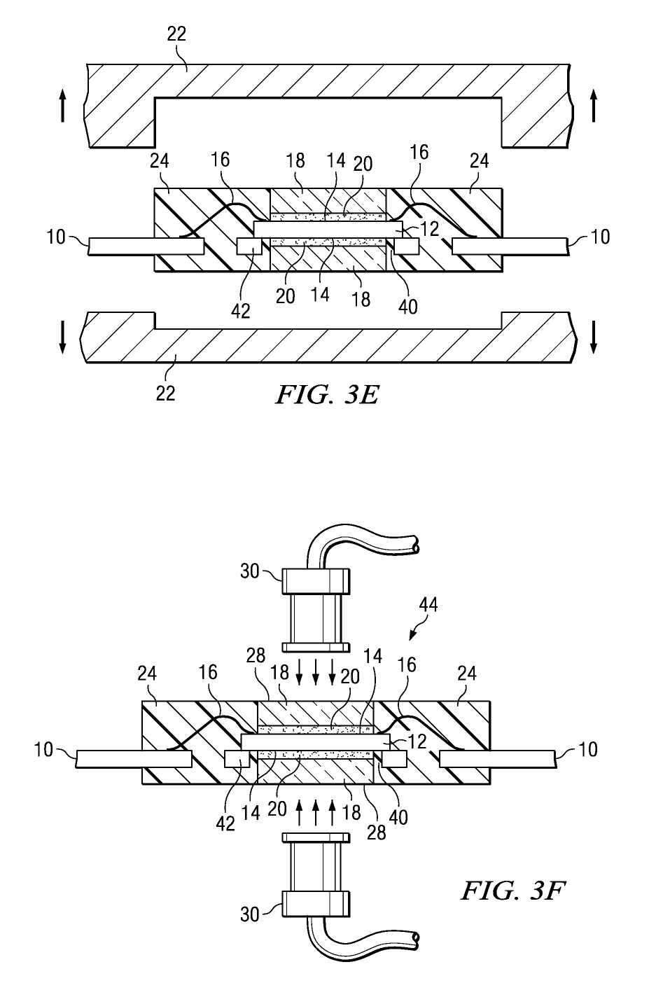

In another example of an alternative embodiment of the invention shown in FIGS. 3A through 3F, an example of a preferred embodiment of the invention having a chip 12 with light-sensitive regions 14 on opposing sides. The opposing light-sensitive regions 14 may be independent, or may, as in this example, be arranged around an aperture 40 in the die paddle 42 of the leadframe 10 in order to permit light transmission to both sides of, or through, the chip 12. As shown in FIG. 3A, the leadframe 10 has an aperture 40, and a chip 12 having light-sensitive regions 14 on each of its opposing sides is affixed to the leadframe 10. Bondwires 16, or flip-chip connections (not shown), for making operable electrical connections are preferably provided. A transparent body 18 is preferably attached to each of the light-sensitive portions 14 of the chip 12. The transparent bodies 18 may be made of various alternative materials without departure from the invention such as elastomeric material, glass, crystal, plastic, epoxy, or other material selected for transparency in the desired segment of the spectrum. A transparent adhesive 20 is preferably used to affix each transparent body 18 to the chip 12. Referring primarily to FIGS. 3B and 3C, the leadframe 10 and chip 12, with the transparent bodies 18 in place, are positioned in a mold 22 positioned to facilitate encapsulation. As above, the transparent adhesive 20 is preferably a pliable material suitable for curing or hardening or otherwise forming a seal at the junctions of the chip 12 and transparent bodies 18. Again, the elasticity of either the adhesive 20 and/or the transparent bodies 18, protect against damage to the light-sensitive portions 14 of the chip 12 when the mold 22 (FIG. 3C) makes contact with the exposed surfaces of each transparent body 18 and, as is typically the case, presses them against the light-sensitive surfaces 14 of the chip 12. The mold 22 preferably excludes mold compound 24, during encapsulation, as shown in FIG. 3D, from at least a portion of the outer surfaces of each of the transparent bodies 18. The encapsulated device 44 is subsequently removed from the mold 22 as illustrated in FIG. 3E, revealing opposing transparent windows 28 formed by at least a part of each transparent body 18. As depicted in FIG. 3F, in the event that an imperfect seal at the mold cavity or other eventualities have permitted the windows 28 to become contaminated with mold compound or other material, the windows 28 may be cleaned 30. It should be apparent to those with ordinary skill in the arts that variations in the steps of the invention are possible, such as for example, attaching the transparent bodies prior to affixing the chip to the leadframe, or forming and curing the transparent bodies in place as in exemplary alternative embodiments described elsewhere herein. An additional advantage of this embodiment is that a pass-through path for light may be provided, which may be desirable in some applications.

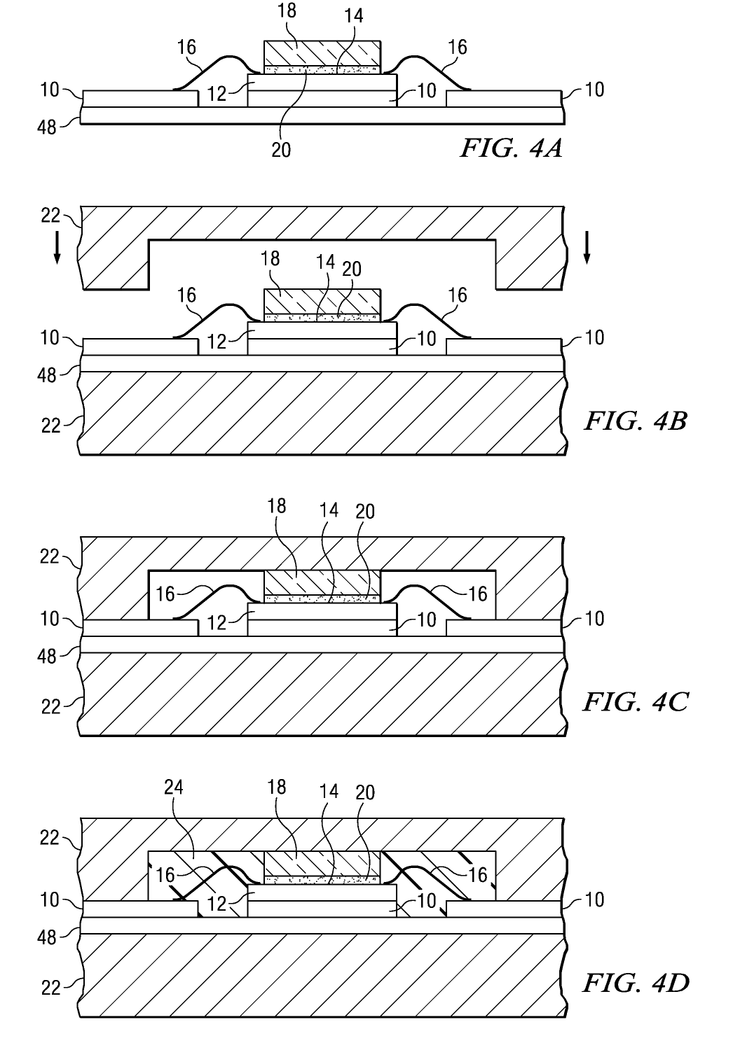

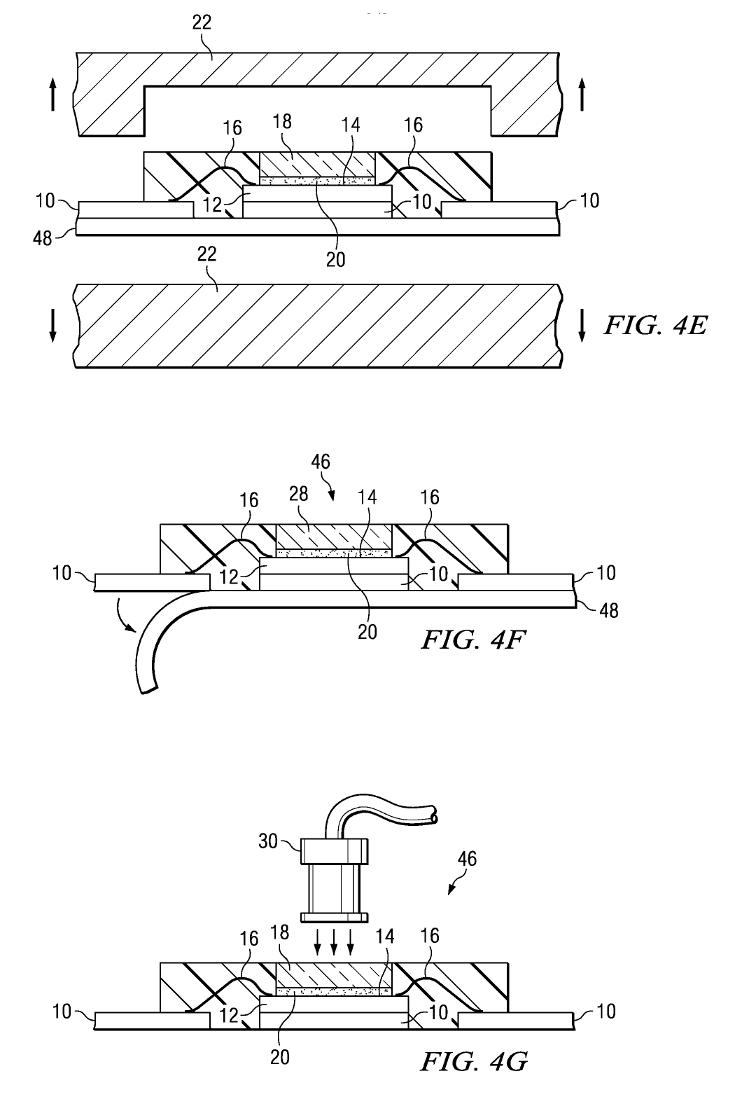

The above examples of preferred embodiments of the invention describe variations of molded plastic-packaged devices in which the chip and leadframe assembly is more-or-less completely surrounded by encapsulant. Additional embodiments are also possible, in which the die paddle is exposed at the bottom of the package. An example of such an alternative embodiment is shown in FIGS. 4A-4G, in which the bottom surface of the leadframe 10 is exposed at the bottom of the package 46. In FIG. 4A, the leadframe 10 is shown attached to a carrier tape 48 as known in the arts. A chip 12 containing a light-sensitive region 14 is affixed to the leadframe 10. Bondwires 16 for making operable electrical connections are preferably provided. A transparent body 18 is preferably attached to the light-sensitive portion 14 of the chip 12 using a transparent adhesive 20 as further described herein. As shown in FIGS. 4B and 4C, the carrier tape 48, leadframe 10, and chip 12 with the transparent body 18 in place, are positioned in a mold 22 and encapsulated. The mold 22 preferably excludes mold compound 24 from at least a portion of the outer surface of the transparent body 18 in order to provide a window 28 on the light-sensitive portion 14 of the chip 12. Following encapsulation, FIGS. 4E through 4G, the package 46 is removed from the mold 22 and cleaned 30 as needed. In this alternative embodiment, during molding the chip 12 is supported by on the bottom of the mold 22. By using the invention to place the window 28 at the top of the chip 12, the compressive force between the window and the bottom of the cavity is reduced.

The methods and apparatus of the invention provide one or more advantages including but not limited to reducing damage to semiconductor devices during manufacturing. While the invention has been described with reference to certain illustrative embodiments, those described herein are not intended to be construed in a limiting sense. For example, variations or combinations of steps in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

We claim:

1. A method for packaging a light-sensitive semiconductor device comprising the steps of:
affixing a transparent body to a light-sensitive surface of the semiconductor device;
affixing the device to a leadframe;
placing the assembled leadframe, device, and transparent body into a mold, the mold configured for contacting the transparent body;
encapsulating the assembled leadframe and device within the mold; and
removing the mold, thereby forming a package encased in encapsulant and having a transparent window aligned with the light-sensitive surface of the device.

2. A method according to claim 1 wherein the step of affixing the transparent body further comprises placing a rigid transparent body on a light-sensitive surface of the semiconductor device.

3. A method according to claim 1 wherein the step of affixing the transparent body further comprises placing a semi-rigid transparent body on a light-sensitive surface of the semiconductor device.

4. A method according to claim 1 wherein the step of affixing the transparent body further comprises interposing transparent adhesive material between the transparent body and the light-sensitive surface of the semiconductor device.

5. A method according to claim 1 wherein the step of affixing the transparent body further comprises:
dispensing a fluid transparent material on a light-sensitive surface of the semiconductor device;
contacting the fluid transparent material on the light-sensitive surface of the semiconductor device with the mold, thereby shaping the fluid transparent material; and
curing the fluid transparent material on the light-sensitive surface of the semiconductor device to form a transparent body.

6. A method according to claim 1 further comprising the step of reiterating the step of affixing a transparent body to a light-sensitive surface of the semiconductor device, thereby forming a package having a plurality of transparent windows aligned to a plurality of light-sensitive surfaces.

7. A method according to claim 1 further comprising the step of cleaning the transparent window.

8. A method according to claim 1 wherein the transparent body further comprises an elastomeric material.

9. A method according to claim 1 wherein the transparent adhesive further comprises an elastomeric material.

10. A method according to claim 1 wherein the transparent adhesive further comprises a fluid material, and further comprising the step of curing the transparent adhesive.

11. A method for packaging a semiconductor device having a light-sensitive surface, comprising the steps of:
affixing the device to a leadframe;
dispensing a fluid transparent material on a light-sensitive surface of the semiconductor device;
placing the assembled leadframe, device, and fluid transparent material into a mold, the mold configured for contacting the fluid transparent material;
contacting the fluid transparent material on the light-sensitive surface of the device with the mold, thereby shaping the fluid transparent material;
curing the fluid transparent material on the light-sensitive surface of the semiconductor device to form a transparent body;
encapsulating the assembled leadframe, device, and transparent body within the mold; and
removing the mold, thereby forming a package encased in encapsulant and having a transparent window aligned with the light-sensitive surface of the device.
